(19) United States
(12) Patent Application Publication
(10) Pub. No.: US 2015/0138700 A1
(43) Pub. Date: May 21, 2015

(54) FLEXIBLE SUBSTRATES FOR WEARABLE DEVICES

(71) Applicants: Dileep Goyal, Fremont, CA (US); Mihai Ionescu, Santa Cruz, CA (US); Hari N. Chakravarthula, San Jose, CA (US)

(72) Inventors: Dileep Goyal, Fremont, CA (US); Mihai Ionescu, Santa Cruz, CA (US); Hari N. Chakravarthula, San Jose, CA (US)

(73) Assignee: AliphCom, San Francisco, CA (US)

(21) Appl. No.: 14/541,064

(22) Filed: Nov. 13, 2014

Related U.S. Application Data
(60) Provisional application No. 61/903,951, filed on Nov. 13, 2013.

(51) Int. Cl. G06F 1/16; H05K 5/06

(52) U.S. Cl. CPC G06F 1/163; H05K 5/065
USPC 361/679.03; 264/272.11

(57) ABSTRACT

Embodiments relate generally to wearable electrical and electronic hardware, computer software, wired and wireless network communications, and to wearable/mobile computing devices. More specifically, various embodiments are directed to, for example, a flexible substrate. In one example, a wearable device may include a framework configured to be worn or attached, and a flexible substrate coupled to the framework. The flexible substrate may include a first end and a second end, and may include one or more conductive layer structures and a conductive laminate structure. The flexible substrate may include rigid regions configured to receive one or more components including a sensor, an electrode, and/or a logic circuit (e.g., bioimpedance logic circuit).

### RELATED APPLICATIONS

This application claims the benefit of U.S. Provisional Patent Application No. 61/903,951 filed Nov. 13, 2013 with Attorney Docket No. ALI-344P, which is herein incorporated by reference. This application incorporates the following applications herein by reference: U.S. patent application Ser. No. 13/942,503 filed Jul. 13, 2013 with Attorney Docket No. ALI-001CIP1CIP1CON1CON1, U.S. patent application Ser. No. 14/______ filed Nov. 13, 2014 with Attorney Docket No. ALI-345 titled “CONDUCTIVE STRUCTURES FOR A FLEXIBLE SUBSTRATE IN A WEARABLE DEVICE,” and U.S. patent application Ser. No. 14/______ filed Nov. 13, 2014 with Attorney Docket No. ALI-346 titled “ALIGNMENT OF COMPONENTS COUPLED TO A FLEXIBLE SUBSTRATE FOR WEARABLE DEVICES, and U.S. patent application Ser. No. 14/480,628 (ALI-516) filed on Sep. 8, 2014.

### FIELD

Embodiments relate generally to wearable electrical and electronic hardware, computer software, wired and wireless network communications, and to wearable/mobile computing devices. More specifically, various embodiments are directed to, for example, a flexible substrate.

### BACKGROUND

Conventional wearable devices, such as data capable bands or wrist bands, typically require circuit boards to be formed from flexible materials. However, some flexible materials are not well-suited to provide sufficient support for electronic devices, such as semiconductor devices, that are mounted on the flexible material. One approach implements stiffener-like structures. While functional, the above-described supporting materials may be sub-optimal.

Thus, what is needed is a solution for implementing a flexible substrate without the limitations of conventional techniques.

### BRIEF DESCRIPTION OF THE DRAWINGS

Various embodiments or examples (“examples”) of the invention are disclosed in the following detailed description and the accompanying drawings:

FIG. 1 illustrates an example of a flexible substrate, according to some embodiments;

FIG. 2 depicts an example of structures used to form a flexible substrate, according to some examples;

FIG. 3 is a diagram depicting an example of a flexible substrate, according to some examples;

FIG. 4 is a diagram depicting a panel of contoured flexible substrates, according to some examples;

FIG. 5 is a diagram showing a side view of a flexible substrate including components coupled to a framework, according to some examples;

FIGS. 6 to 8 are diagrams showing different views of an extension portion of an encapsulated component, according to some examples;

FIG. 9 is an example of a flow for implementing a flexible substrate, according to some embodiments;

FIG. 10 depicts an example of structures used to form a flexible substrate coupled to one or more electrodes, according to some examples;

FIG. 11 depicts an example of structures used to form a flexible substrate coupled to one or more logic circuits, according to some examples;

FIG. 12 depicts an example of structures used to form a flexible substrate coupled to one or more antenna structures, according to some examples; and

FIG. 13 depicts an example of structures used to form a flexible substrate coupled to one or more near-field antenna structures, according to some examples.

### DETAILED DESCRIPTION

Various embodiments or examples may be implemented in numerous ways, including as a system, a process, an apparatus, a user interface, or a series of program instructions on a computer readable medium such as a computer readable storage medium or a computer network where the program instructions are sent over optical, electronic, or wireless communication links. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For clarity, technical material that is known in the technical fields related to the examples has not been described in detail to avoid unnecessarily obscuring the description.

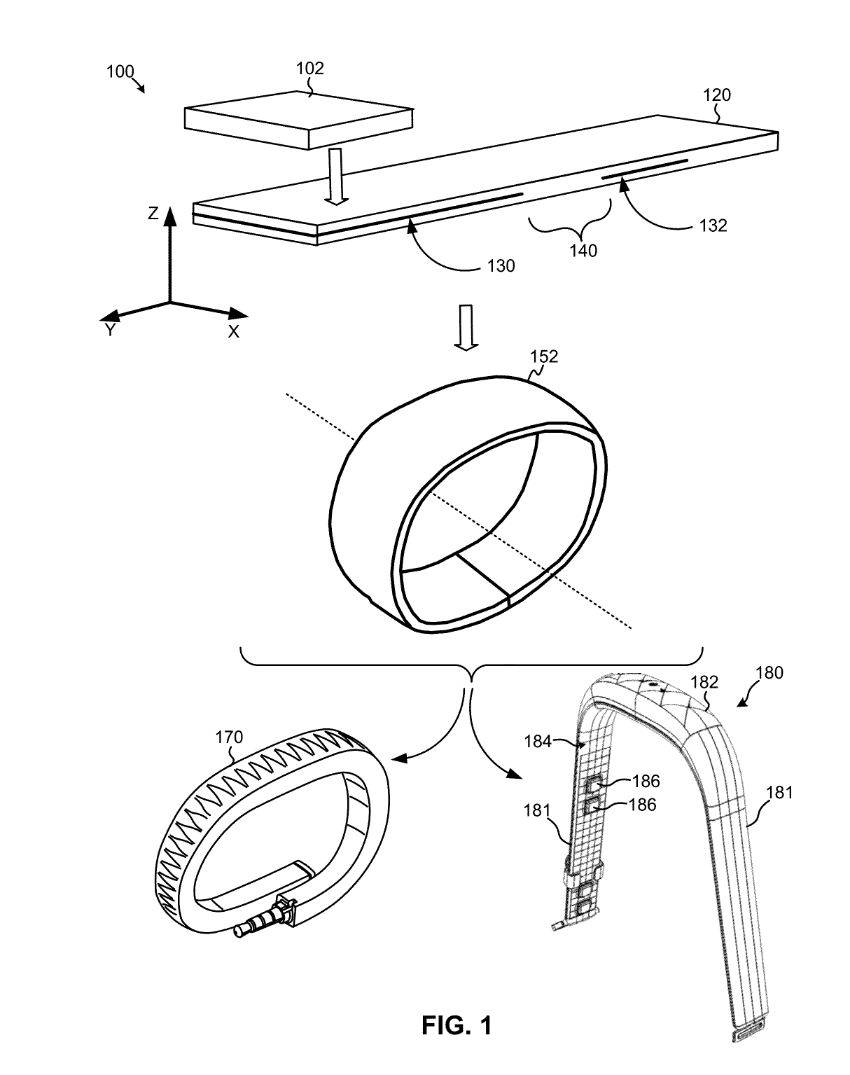

FIG. 1 illustrates an example of a flexible substrate, according to some embodiments. Diagram 100 depicts a flexible substrate 120 that includes a first subset of one or more layers 130 and 132 configured to provide rigid regions upon which to, for example, mount or otherwise support a component 102, such as a sensor, a vibratory motor, or an electronic device (e.g., a semiconductor device). Further, flexible substrate 120 also includes one or more non-rigid regions 140. In various examples, non-rigid regions 140 can include a variety of structures to provide varying degrees of flexibility and/or support. As depicted in diagram 100, flexible substrate 120 and its components mounted thereupon are coupled to framework 152 to form a constituent part of the wearable device 170. Framework 152 can be configured to be formed in any shape, such as an ellipse, a circle, and/or helical shape, so that wearable device 170 can be worn around a wrist or other appendage of a user. Wearable device 170 can be formed when flexible substrate 120 and framework 152 are overmolded.

Framework 152, in some examples, may include at least interior structures of a wearable pod 182 or may include a cradle structure as described in U.S. patent application Ser. No. 14/480,628 (ALI-516) filed on Sep. 8, 2014, which is herein incorporated by reference.

In some examples, as depicted in diagram 100, flexible substrate 120 and its components mounted thereupon are coupled to framework 152 to form a constituent part of a wearable device 180. In the example shown, wearable device 180 may include a wearable pod 182 that can include logic, including processors and memory, configured to detect, among other things, physiological signals via bioimpedance signals. In one example, wearable pod 182 can include bioimpedance circuitry configured to drive bioimpedance through one electrode 186 disposed in a band or strap 181. Strap 181 may be integrated or removable coupled to wearable pod 182.

One or more flexible substrates (not shown) may include conductive materials disposed in interior 184 of band or strap 181 to, for example, couple electrodes 186 to logic (or any other component) in wearable pod 182 or any other portion of wearable device 180. In at least one example, electrodes 186 can be implemented to facilitate transmission of bioimpedance signals to determine physiological signals or characteristics, such as heart rate. Further, electrodes 186 may also be coupled via a flexible substrate to a galvanic skin response (“GSR”) logic circuit.

A wearable pod and/or wearable device may be implemented as data-mining and/or analytic device that may be worn as a strap or band around or attached to an arm, leg, ear, ankle, or other bodily appendage or feature. In other examples, a wearable pod and/or wearable device may be carried, or attached directly or indirectly to other items, organic or inorganic, animate, or static. Note, too, that wearable pod enough be integrated into or with a strap 181 or band and can be shaped other than as shown. For example, a wearable pod circular or disk-like in shape with a display portion disposed on one of the circular surfaces.

According some embodiments, logic disposed in wearable pod (or disposed anywhere in wearable device, such as in strap 181) may include a number of components formed in either hardware or software, or a combination thereof, to provide structure and/or functionality therein. In particular, the logic may include a touch-sensitive input/output (“I/O”) controller to detect contact with portions of a pod cover or interface, a display controller to facilitate emission of light, an activity determinator configured to determine an activity based on, for example, sensor data from one or more sensors (e.g., disposed in an interior region within wearable pod 182, or disposed externally). A bioimpedance (“BI”) circuit may facilitate the use of bioimpedance signals to determine a physiological signal (e.g., heart rate), and a galvanic skin response (“GSR”) circuit may facilitate the use of signals representing skin conductance. A physiological (“PHY”) signal determinator may be configured to determine physiological characteristic, such as heart rate, among others, and a temperature circuit may be configured to receive temperature sensor data to facilitate determination of heat flux or temperature. A physiological (“PHY”) condition determinator may be configured to implement heat flux or temperature, or other sensor data, to derive values representative of a condition (e.g., a biological condition, such as caloric energy expended or other calorimetry-related determinations). Logic can include a variety of other sensors and other logic, processors, and/or memory including one or more algorithms.

Examples of wearable device 180 and one or more components, including flexible substrates and/or conductive structures, as well as electrodes, may be described in U.S. patent application Ser. No. 14/480,628 (ALI-516) filed on Sep. 8, 2014, which is herein incorporated by reference.

In view of the foregoing, the structures and/or functionalities of flexible substrate 120 and its constituent structures can enhance the reliability of a wearable device 170. In some examples, a conductive laminate structure is disposed in a central layer of flexible substrate 120. For example, the conductive laminate structure can include a flexible copper clad laminate (“FCCL”), including, but not limited to, a resin-coated copper (“RCC”), a rolled and annealed copper (“RA copper”), and the like. The conductive laminate structure can provide enhanced reliability. Further, flexible substrate 120 may omit a stiffener structure that otherwise might introduce gaps into the layers of flexible substrate 120. Additionally, intermediate support structures can be included, each of which include one or more intermediate layers. In some examples, the intermediate support structures can be varied to provide varied amounts of flexibility in the different portions of flexible substrate 120. An intermediate support structure can be formed as, for example, a double coverlay structure (or a multiple coverlay structure) in accordance with some embodiments. Such intermediate support structures can thereby enhance process control during PCB manufacturing, which, in turn, can provide enhanced reliability (e.g., by reducing or eliminating gaps).

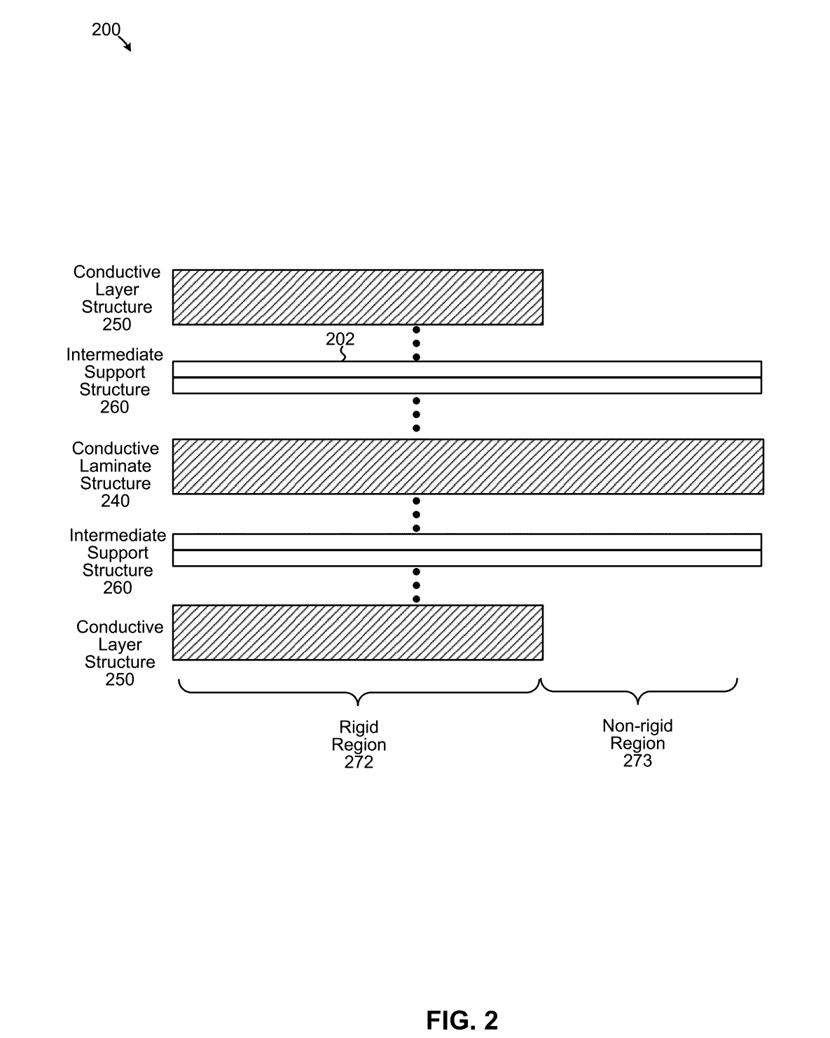

FIG. 2 depicts an example of structures used to form a flexible substrate, according to some examples. Diagram 200 depicts a conductive laminate structure 240 disposed between two or more intermediate support structures 260, each intermediate support structure 260 being composed of multiple intermediate layers 202. As shown, conductive layer structures 250 can form rigid regions 272, which can also be referred to as “rigid islands.” Rigid regions 272 are configured to receive one or more components, including a sensor. Further, at least one rigid region 272 can include a portion of one or more conductive layer structures 250, a portion of a conductive laminate structure 240 and portions of one or more intermediate support structures 260. Such portions can be stacked upon each other. Non-rigid regions 273 can exclude or otherwise omit conductive layer structures 250. As will be discussed, non-rigid region 273 can include supported flex regions and/or flex regions that can provide varying degrees of flexibility.

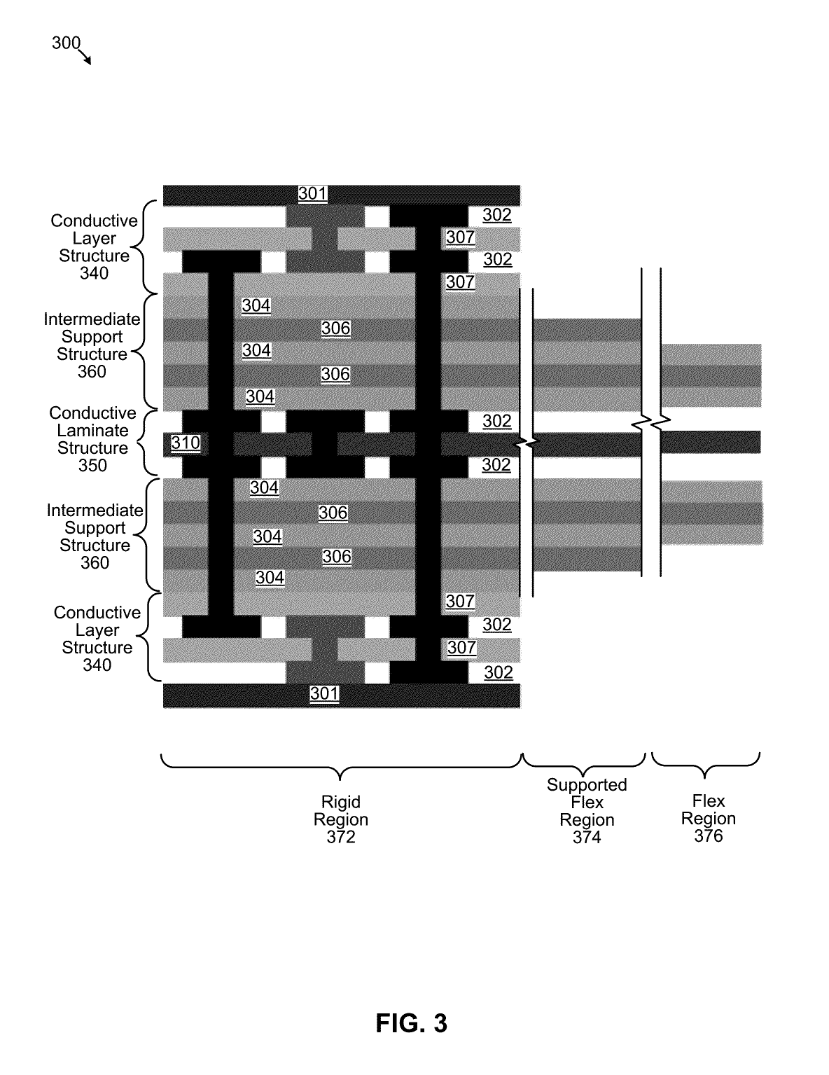

FIG. 3 is a diagram depicting an example of a flexible substrate, according to some examples. Diagram 300 shows a conductive laminate structure 350 extending through a rigid region 372, a supported flex region 374, and a flex region 376. Intermediate support structures 360 extend through rigid region 372, supported flex region 374 and flex region 376. Note that in some examples, intermediate support structures 360 can include fewer intermediate layers in flex region 376 than in the other regions. In some cases, this provides enhanced flexibility relative to the other regions. Further, conductive layer structures 340 disposed above and below intermediate support structures 360.

In the example shown, conductive layer 340 can include conductive structures 302, such as plated copper, on both sides of a composite material 370 (e.g., FR4 or the like). In rigid region 372 and supported flex region 374, intermediate support structures 360 can include multiple intermediate layers 306 formed with layers of adhesive 304. In flex region 376, each intermediate support structure 360 can be composed of at least one intermediate layer 306. Conductive laminate structure 350 can include plated copper layers 302 and a center layer 310.

In some examples, intermediate layers 306 can include a polyimide structure and can have thicknesses substantially equivalent to 25 μm, as an example. As another example, plated copper layer 302 can have a thickness of 30 μm, whereas central layer 310 can be a polyamide structure having a thickness substantially equivalent to 25 μm. Diagram 300 also includes optional layers 301 composed of a solder mask material. Note that the structures identified above in FIG. 3 are not intended to be limiting and can be formed in varied ways using, for example, equivalent materials and dimensions.

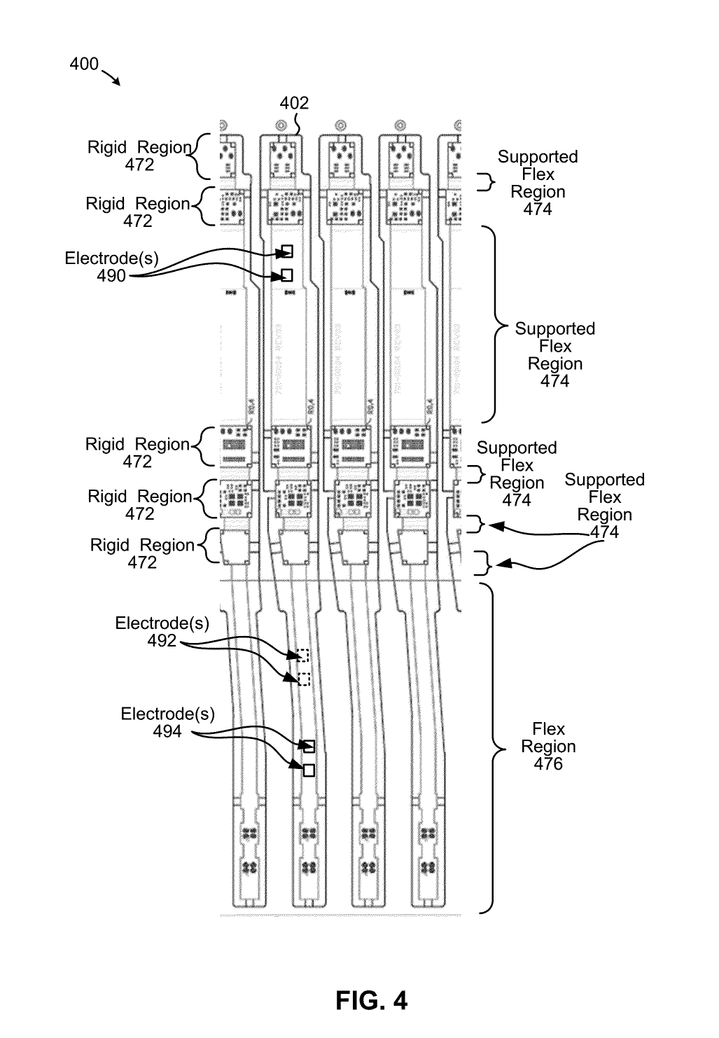

FIG. 4 is a diagram depicting a panel of contoured flexible substrates, according to some examples. Diagram 400 shows flexible substrates 402 giving a first end 403 and a second end 405. Flexible substrates 402 include supported flex regions 474 and a flex region 476. Disposed adjacent to supported flex regions 474 are a number of rigid regions 472 that are configured to support a component. In some examples, at least two intermediate support structures are disposed between rigid regions 472 to form a supported flex region 474. As such, four or more intermediate layers can be disposed in a supported flex region 474. A flex region 476 can be disposed between a rigid region 472 and end 405, and can include two intermediate layers.

In some examples, as depicted in diagram 400, electrodes 494 may be disposed and/or electrically coupled in a flex region 476 to align with a blood vessel (e.g., an artery) or tissue when a wearable device is worn, for example, around a wrist. Flex region 476 may include an electrode buss in which conductive materials establish electrical coupling between bioimpedance circuits (e.g., disposed in rigid regions 472 or elsewhere) and electrodes 494, as well as other electrodes, such as electrodes 492 disposed in a common strap. In some cases, electrodes 490 may be disposed in another region, such as a supported flex region 474 (or elsewhere), and may be disposed in another strap.

Examples of one or more wearable device components, including flexible substrates and/or conductive structures, as well as electrodes, may be described in U.S. patent application Ser. No. 14/480,628 (ALI-516) filed on Sep. 8, 2014, which is herein incorporated by reference.

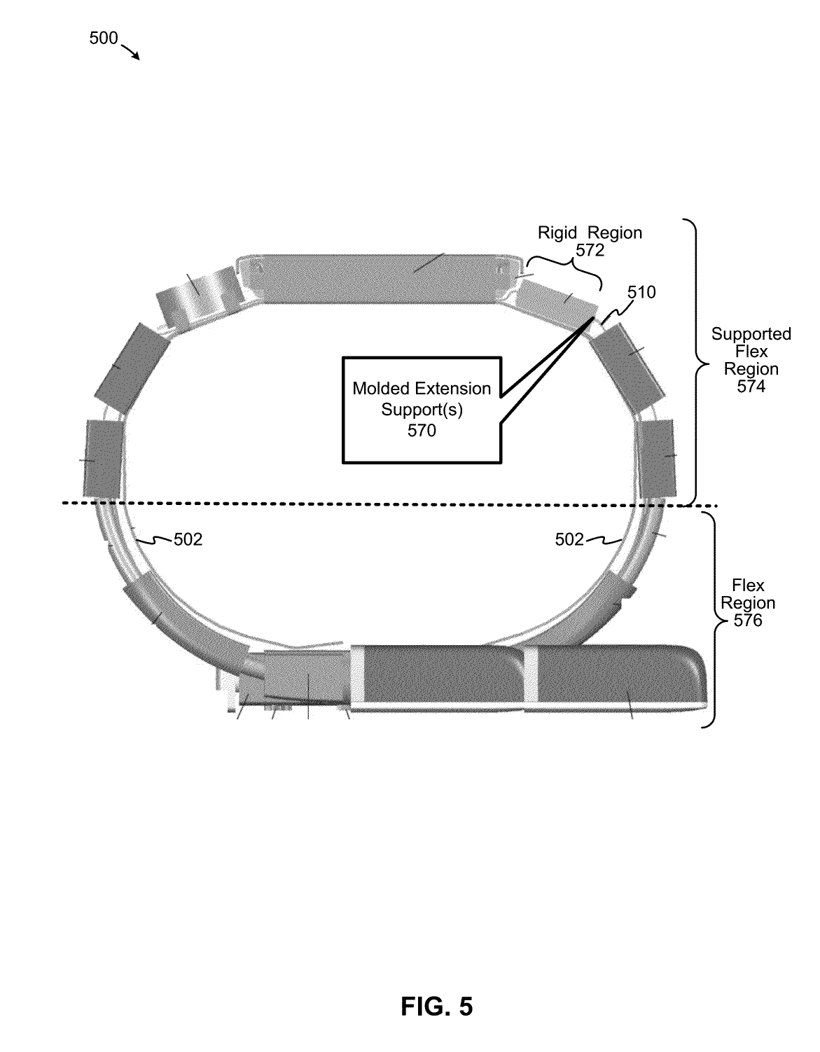

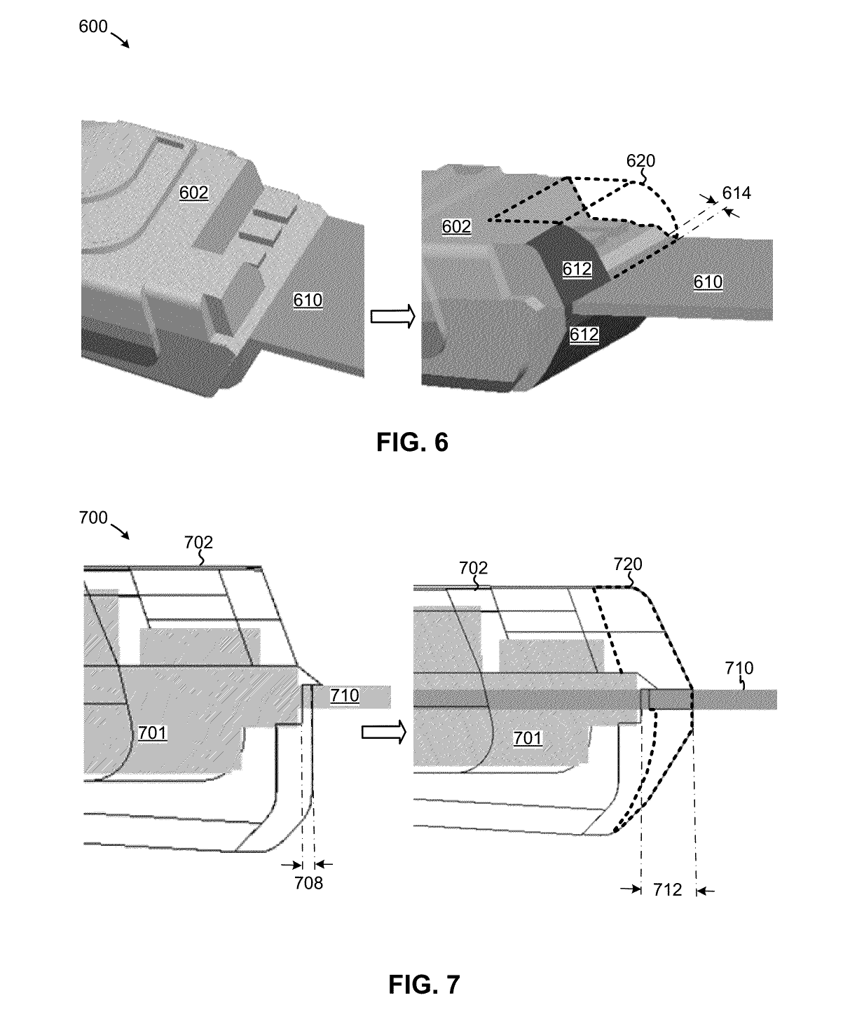

FIG. 5 is a diagram showing a side view of a flexible substrate including components coupled to a framework, according to some examples. Diagram 500 shows a flexible substrate 510 coupled to a framework 502, flexible substrate 510 having areas including supported flex region(s) 574 and flex region(s) 576. Flexible substrate 510 can include a number of components mounted thereupon including, a sensor 514, a vibratory motor 512, and the like. In some cases, such components are mounted or otherwise coupled to flexible substrate 510 in a rigid region 572. In some examples, a component can be overmolded with a low pressure molding material that can include molded extension supports 570, examples of which are provided in FIGS. 6 to 8.

FIGS. 6 to 8 are diagrams showing different views of an extension portion of an encapsulated component, according to some examples. Diagram 600 shows a flexible substrate 610 coupled to an encapsulated component 602. Further, one or more extension portions 612 and/or 620 can be formed to overlap unto or over one or more surfaces of flexible substrate 610. For example, an extension portion 620 and/or 612 can overlap flexible substrate 610 by distance 614.

Diagram 700 of FIG. 7 shows a side view of an encapsulant 702 that covers in encapsulated component 701, which is coupled to flexible substrate 710. As shown, a volume of encapsulant material 720 can be added to enhance the coverage of one or more surfaces of flexible substrate 710 from a distance of 708 to a distance of 712. An example of distance 712 includes, but is not limited to, a distance of 0.9 mm (+/−0.6 mm).

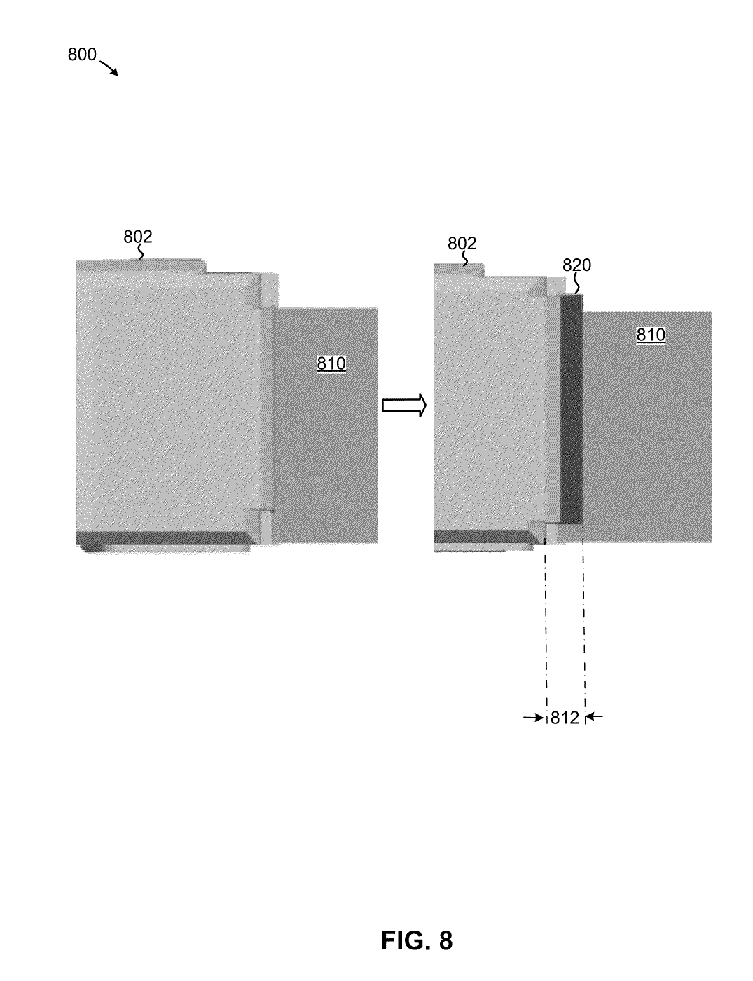

Diagram 800 of FIG. 8 shows a bottom view of an encapsulated component 802 extending over a surface of a flexible substrate 810. As shown, additional encapsulant material can be used to form a ridge 820 to support the bottom of flexible substrate 810 (e.g., the surface facing a user or an inner axis about which flexible substrate 810 is wrapped). In this example, ridge 820 extends at a distance 812 under the bottom of flexible substrate 810 to provide support and stress relief, among other reasons.

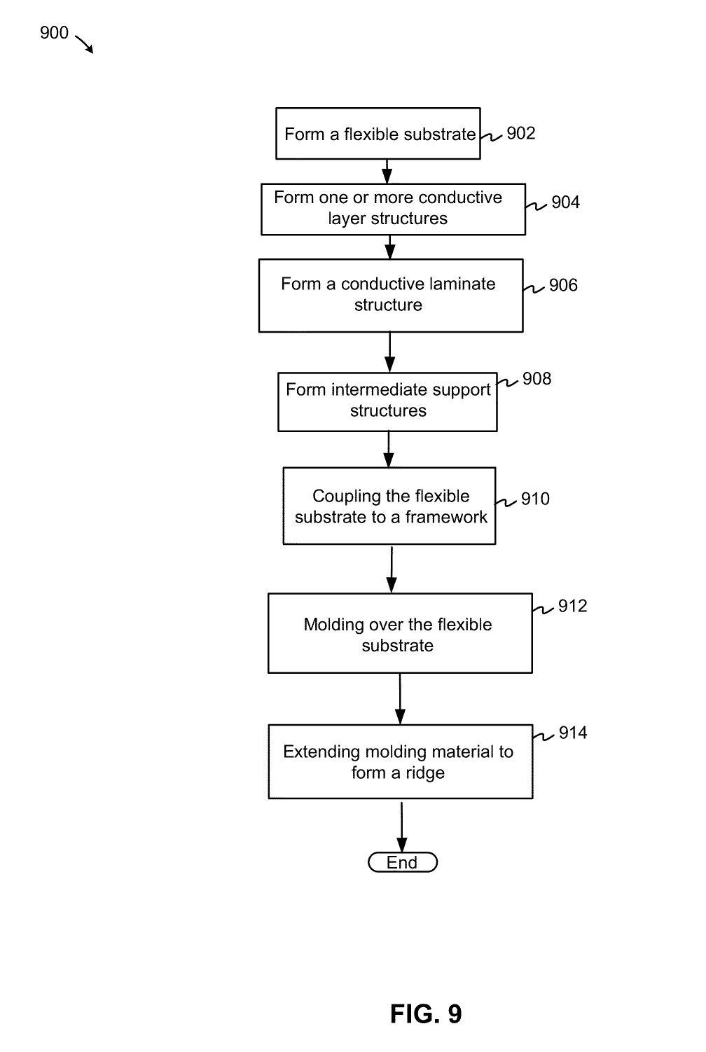

FIG. 9 is an example of a flow for implementing a flexible substrate, according to some embodiments. Flow diagram 900 is initiated at 902, at which a flexible substrate is formed. For example, one or more conductive layer structures can be implemented at 904. At 906, a conductive laminate structure can be implemented with intermediate support structures that are formed at 908. At 910, the flexible substrate is coupled to a framework, and at 912 a molding material encapsulates a component of the flexible substrate. At 914, a molding material is extended to form a ridge support for a flexible substrate. Flow 900 terminates at 916.

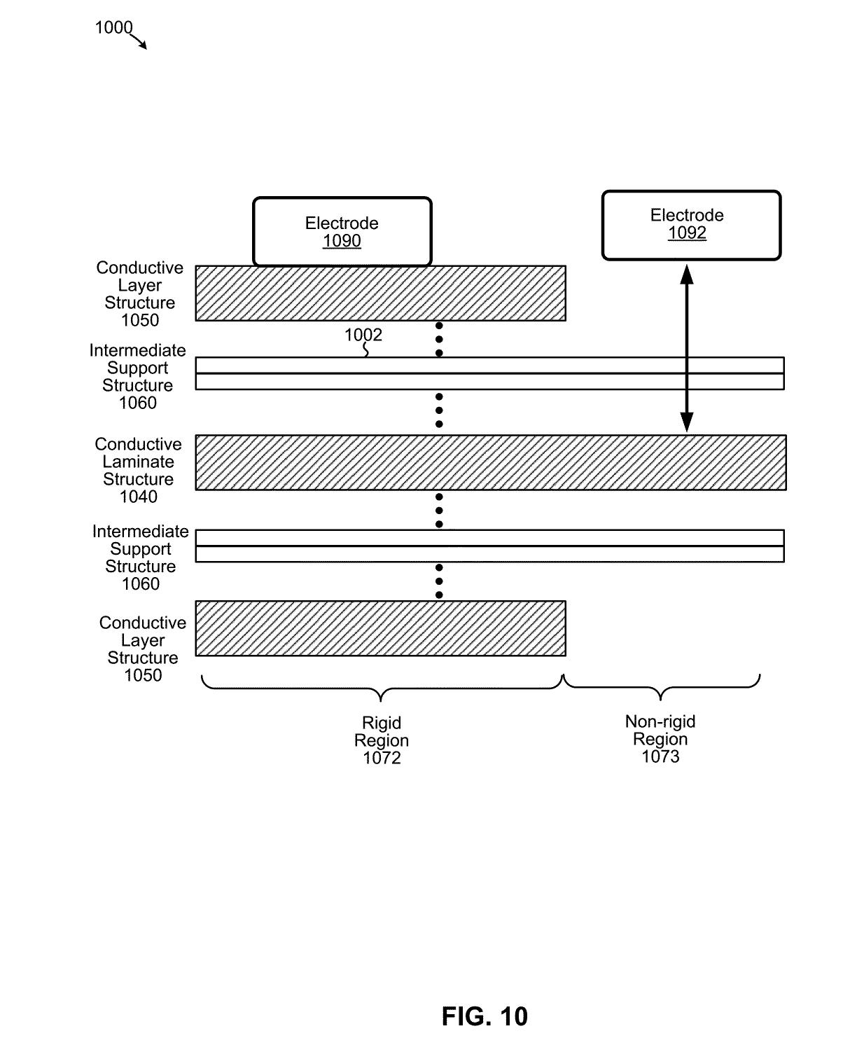

FIG. 10 depicts an example of structures used to form a flexible substrate coupled to one or more electrodes, according to some examples. Diagram 1000 depicts elements having structures and/or functions as similarly-named or similarly-numbered elements of FIG. 2, according to some examples. In this example, diagram 1000 depicts a conductive laminate structure 1040 disposed between two or more intermediate support structures 1060, each intermediate support structure 1060 being composed of multiple intermediate layers 1002. As shown, conductive layer structures 1050 can form rigid regions 1072. Rigid regions 1072 are configured to receive one or more components, including a sensor or logic circuitry. Further, at least one rigid region 1072 can include a portion of one or more conductive layer structures 1050, a portion of a conductive laminate structure 1040 and portions of one or more intermediate support structures 1060. Such portions can be stacked upon each other. Note that in some examples, an electrode 1090 can be disposed in rigid region 1072 and may be electrically coupled to one or more conductive layer structures 1050 and/or one or more conductive laminate structures 1040.

Non-rigid regions 1073 can exclude or otherwise omit conductive layer structures 1050. Note that non-rigid region 1073 can include supported flex regions and/or flex regions that can provide varying degrees of flexibility. Note that in some examples, an electrode 1092 can be disposed in non-rigid region 1073 and may be electrically coupled to one or more conductive layer structures 1050 and/or one or more conductive laminate structures 1040.

Note that examples of structures and/or functions that may be implemented using flexible substrates and/or conductive structures, as well as electrodes (or other wearable device components), are described in U.S. patent application Ser. No. 14/480,628 (ALI-516) filed on Sep. 8, 2014, which is herein incorporated by reference.

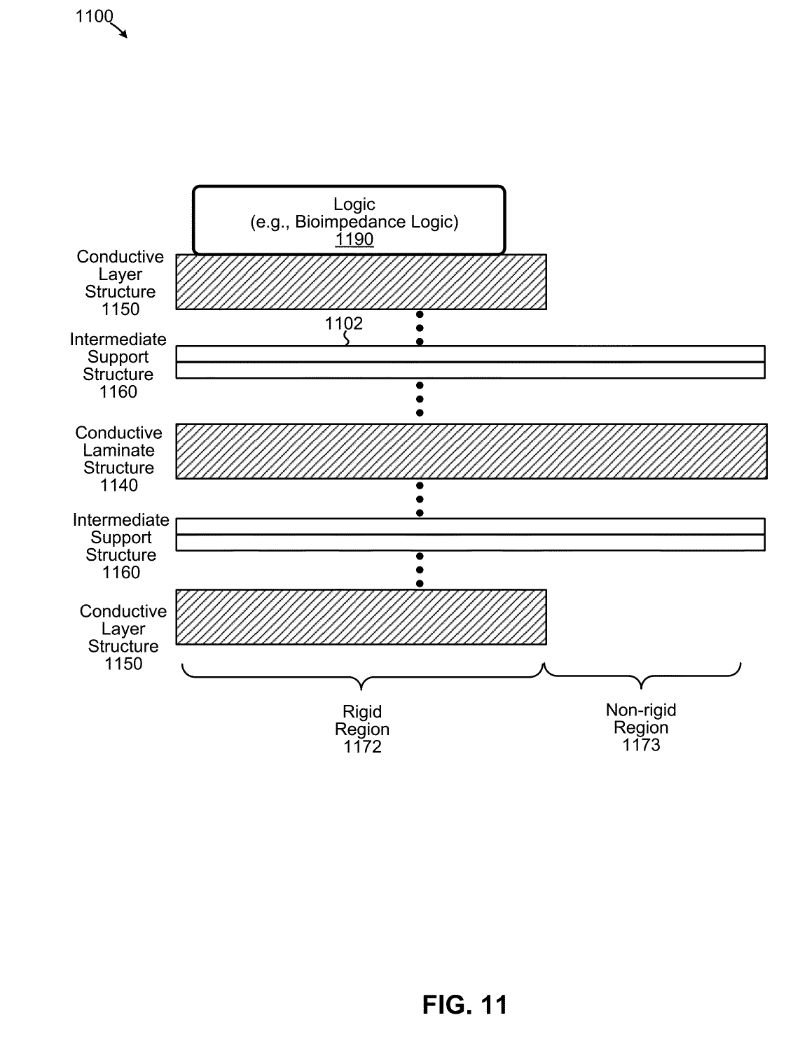

FIG. 11 depicts an example of structures used to form a flexible substrate coupled to one or more logic circuits, according to some examples. Diagram 1100 depicts elements having structures and/or functions as similarly-named or similarly-numbered elements of FIGS. 2 and/or 10, according to some examples. In this example, diagram 1100 depicts a conductive laminate structure 1140 disposed between two or more intermediate support structures 1160, each intermediate support structure 1160 being composed of multiple intermediate layers 1102. As shown, conductive layer structures 1150 can form rigid regions 1172. Rigid regions 1172 are configured to receive one or more components, including a sensor or logic circuitry. In the example shown, logic (e.g., bioimpedance logic or circuitry, or GSR logic or circuitry) 1190 can be disposed in rigid region 1172. In implementations in which logic 1190 is formed in a semiconductor device, rigid region 1172 is configured to provide structural support to buttress against stresses that may arise during wearing of a wearable device.

Further, at least one rigid region 1172 can include a portion of one or more conductive layer structures 1150, a portion of a conductive laminate structure 1140 and portions of one or more intermediate support structures 1160. Such portions can be stacked upon each other. Note that in some examples, logic 1190 can be disposed in rigid region 1172 and may be electrically coupled to one or more conductive layer structures 1150 and/or one or more conductive laminate structures 1140.

Note that examples of structures and/or functions that may be implemented using flexible substrates and/or conductive structures, as well as logic and/or circuitry (or other wearable device components), are described in U.S. patent application Ser. No. 14/480,628 (ALI-516) filed on Sep. 8, 2014, which is herein incorporated by reference.

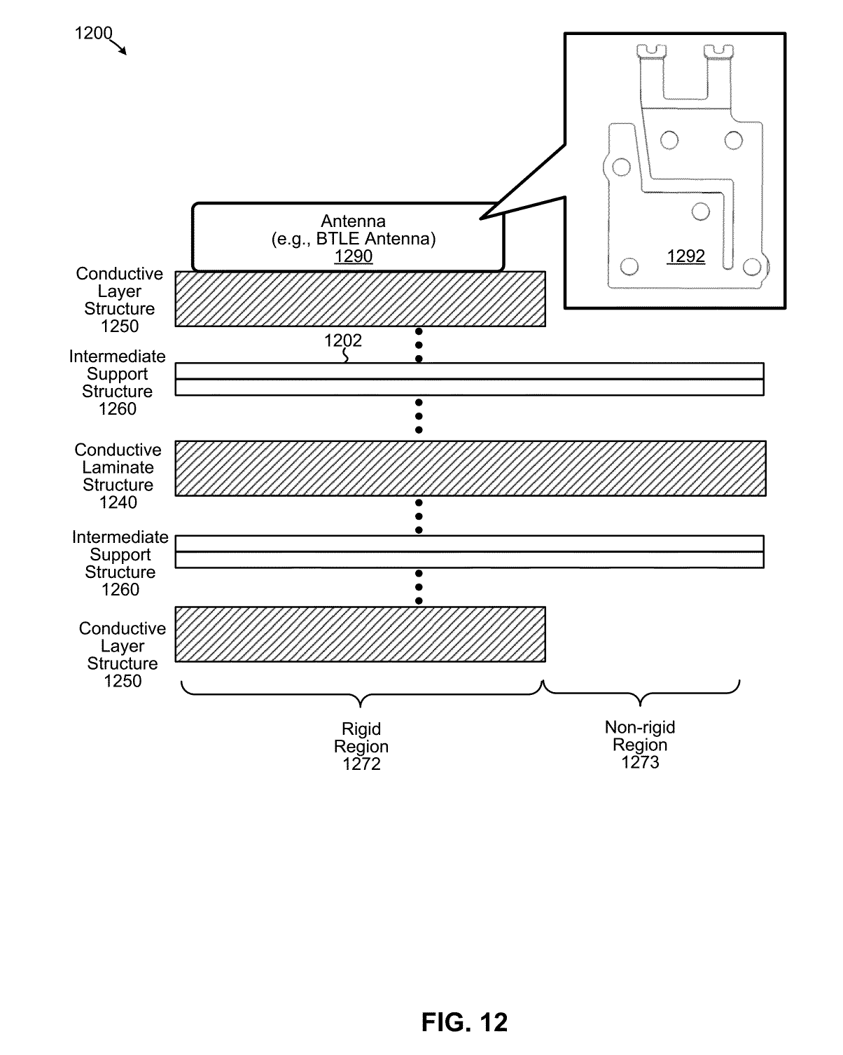

FIG. 12 depicts an example of structures used to form a flexible substrate coupled to one or more antenna structures, according to some examples. Diagram 1200 depicts elements having structures and/or functions as similarly-named or similarly-numbered elements of FIGS. 2 and/or 11, according to some examples. In this example, diagram 1200 depicts a conductive laminate structure 1240 disposed between two or more intermediate support structures 1260, each intermediate support structure 1260 being composed of multiple intermediate layers 1202. As shown, conductive layer structures 1250 can form rigid regions 1272. Rigid regions 1272 are configured to receive one or more components, including a sensor or logic circuitry. In the example shown, an antenna structure 1290 can be disposed in rigid region 1272. In implementations in which antenna structure 1290 is formed in rigid region 1272 is configured to provide structural support to buttress against stresses that may arise during wearing of a wearable device. Further, antenna structure 1290 can be disposed anywhere in a wearable device or strap so as to reduce or minimize exposure to adjacent electronic circuitry that otherwise might interfere electromagnetically with antenna structure 1219. Thus, rigid region 1272 need not be disposed in a wearable pod (e.g., wearable pod 182).

Further, at least one rigid region 1272 can include a portion of one or more conductive layer structures 1250, a portion of a conductive laminate structure 1240 and portions of one or more intermediate support structures 1260. Such portions can be stacked upon each other. Note that in some examples, antenna structure 1290 can be disposed in rigid region 1272 and may be electrically coupled to one or more conductive layer structures 1250 and/or one or more conductive laminate structures 1240. As an example, antenna structure 1290 can be implemented as an short-ranged configured antenna 1292, to, for example, communicate BlueTooth®-related (including BlueTooth Low Energy) radio signals.

Note that examples of structures and/or functions that may be implemented using flexible substrates and/or conductive structures, as well as antennas and/or circuitry (or other wearable device components), are described in U.S. patent application Ser. No. 14/480,628 (ALI-516) filed on Sep. 8, 2014, which is herein incorporated by reference.

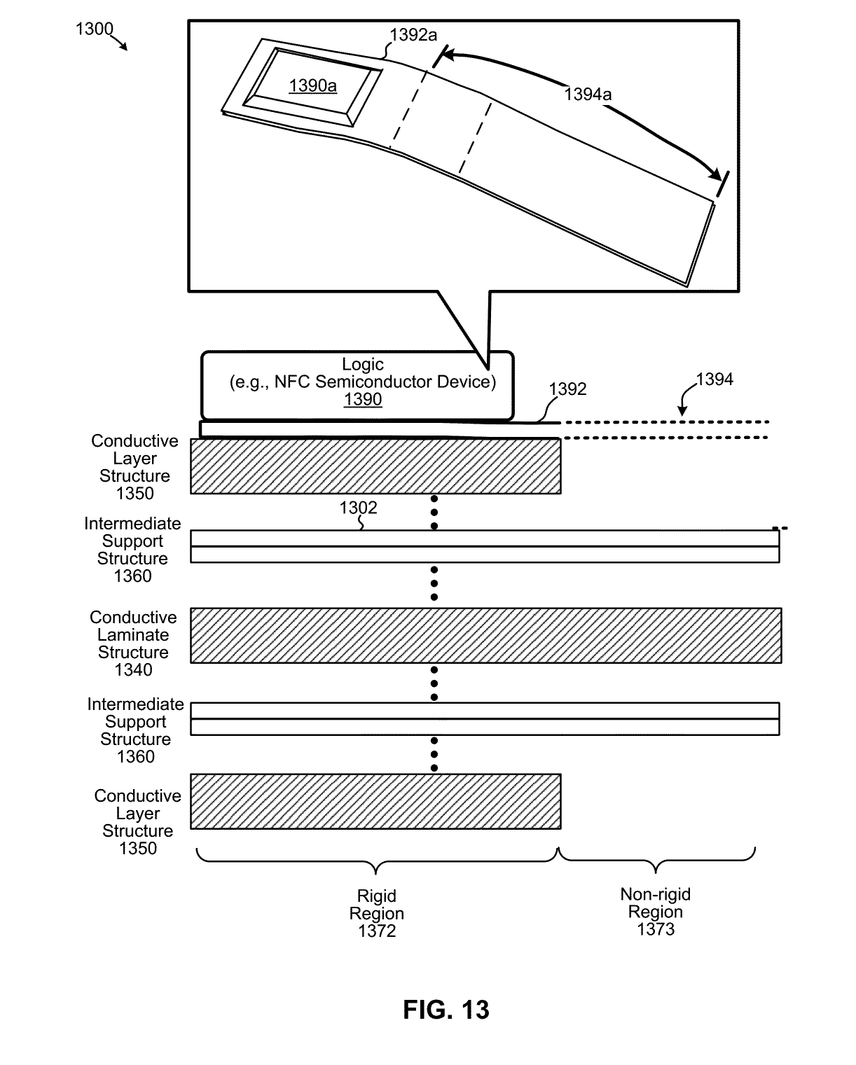

FIG. 13 depicts an example of structures used to form a flexible substrate coupled to one or more near-field antenna structures, according to some examples. Diagram 1300 depicts elements having structures and/or functions as similarly-named or similarly-numbered elements of FIGS. 2 and/or 12, according to some examples. In this example, diagram 1300 depicts a conductive laminate structure 1340 disposed between two or more intermediate support structures 1360, each intermediate support structure 1360 being composed of multiple intermediate layers 1302. As shown, conductive layer structures 1350 can form rigid regions 1372. Rigid regions 1372 are configured to receive one or more components, including logic circuitry.

In the example shown, logic 1390 can be disposed in rigid region 1372. Logic 1390 can be an electronic device configured to facilitate near-field radio signal communications via an antenna including a first portion 1392 and a second portion 1394. As shown, logic 1390 can be mounted upon, and/or coupled to, a portion 1392 of the antenna in rigid region 1372, whereas portion 1394 may extend into or over non-rigid region 1373. In one implementation, logic 1390 can include an NFC semiconductor-based device 1390a configured to facilitate near-field communications (“NFC”). Further, NFC device 1390a can be mounted upon, and/or coupled to, a portion 1392a of an NFC antenna, whereby a portion 1394a may be disposed in a non-rigid region.

In implementations in which logic 1390 is formed in rigid region 1372, the rigid region may be configured to provide structural support to buttress against stresses that may arise during wearing of a wearable device. Further, logic 1390 can be disposed anywhere in a wearable device or strap so as to reduce or minimize exposure to adjacent electronic circuitry that otherwise might interfere electromagnetically with an NFC antenna structure. Thus, rigid region 1372 need not be disposed in a wearable pod (e.g., wearable pod 182 of FIG. 1).

Further, at least one rigid region 1372 can include a portion of one or more conductive layer structures 1350, a portion of a conductive laminate structure 1340 and portions of one or more intermediate support structures 1360. Such portions can be stacked upon each other. Note that in some examples, logic 1390 and/or antenna portions 1392 and 1394 may be electrically coupled to one or more conductive layer structures 1350 and/or one or more conductive laminate structures 1340.

Note that examples of structures and/or functions that may be implemented using flexible substrates and/or conductive structures, as well as antennas and/or circuitry (or other wearable device components), are described in U.S. patent application Ser. No. 14/480,628 (ALI-516) filed on Sep. 8, 2014, which is herein incorporated by reference.

Although the foregoing examples have been described in some detail for purposes of clarity of understanding, the above-described inventive techniques are not limited to the details provided. There are many alternative ways of implementing the above-described invention techniques. The disclosed examples are illustrative and not restrictive.

1. A wearable device comprising:
a framework configured to be worn or attached; and
a flexible substrate coupled to the framework, the flexible substrate having a first end and a second end and comprising:
one or more conductive layer structures;
a conductive laminate structure; and
a plurality of intermediate support structures,
wherein the flexible substrate includes one or more rigid regions configured to receive one or more components including a sensor.

2. The wearable device of claim 1 wherein at least a rigid region of the rigid regions comprises:
a portion of the one or more conductive layer structures, a portion of the conductive laminate structure, and a portion of the plurality of intermediate support structures,
wherein the portions are stacked upon each other.

3. The wearable device of claim 1 wherein the rigid regions comprise:
at least one of the sensor, a vibratory motor, and an electronic device.

4. The wearable device of claim 1 wherein the flexible substrate further comprises:
at least two intermediate support structures of the plurality of the intermediate support structures in which the conductive laminate structure is disposed between the two intermediate support structures.

5. The wearable device of claim 1 wherein the flexible substrate further comprises:
one or more supported flex regions.

6. The wearable device of claim 5 wherein the one or more supported flex regions each comprises:
at least two intermediate support structures of the plurality of the intermediate support structures disposed between a first rigid region and a second rigid region.

7. The wearable device of claim 6 wherein each of the two intermediate support structures comprises:
two intermediate layers.

8. The wearable device of claim 7 wherein each of the two intermediate layers comprises:
a polyimide layer.

9. The wearable device of claim 1 wherein the flexible substrate further comprises:
one or more flex regions.

10. The wearable device of claim 9 wherein the one or more flex regions each comprises:
at least two intermediate support structures of the plurality of the intermediate support structures disposed between a third rigid region and one of the first or the second ends.

11. The wearable device of claim 10 wherein each of the two intermediate support structures comprises:
one intermediate layer.

12. The wearable device of claim 1 wherein at least one of the rigid regions comprises:
a molding material encapsulating one of the components.

13. The wearable device of claim 12 wherein the molding material comprises:
an extension portion that encapsulates a portion of a supported flex region.

14. The wearable device of claim 13 wherein extension portion comprises:
a ridge supporting the portion of a supported flex region.

15. The wearable device of claim 1 wherein the flexible substrate comprises:
electrodes.

16. The wearable device of claim 1 wherein a rigid region comprises:
a logic circuit.

17. The wearable device of claim 1 wherein the sensor comprises:
electrodes;
one or more of the conductive layer structures; and
a bioimpedance logic circuit.

18. A method comprising:
forming a flexible substrate including:
one or more conductive layer structures;
a conductive laminate structure; and
a plurality of intermediate support structures;
coupling the flexible substrate to a framework; and
molding over the flexible substrate and the framework,
wherein the flexible substrate includes one or more rigid regions configured to receive one or more components including a sensor.

19. The method of claim 18, further comprising:
disposing the conductive laminate structure between multiple intermediate layers, each of which is a constituent of at least one of plurality of intermediate support structures.

20. The method of claim 18, further comprising:
molding over a component in a rigid region; and
extending a molding material to form a ridge contacting a surface portion of a supported flex region.
